(19) United States
(12) Patent Application Publication
(10) Pub. No.: US 2004/0207426 A1
(43) Pub. Date: Oct. 21, 2004

(54) Active prematching tuner system

(76) Inventor: Christos Tsironis, Kirkland (CA)

Correspondence Address: CHRISTOS TSIRONIS, FOCUS MICROWAVES INC., 1603 ST. REGIS, DOLLARD DER ORMEAUX, QC, H9B3H7, CA

(21) Appl. No.: 10/418,633

(22) Filed: Apr. 21, 2003

(51) Int. Cl. G01R 31/02

(52) U.S. Cl. 324/764

(57) ABSTRACT

An active load (source) pull measurement set-up comprising two circulators, one band pass filter, one power amplifier, one variable attenuator, one stabilization tuner, one prematching tuner and one load (source) tuner; the microwave stability of the set-up is improved by means of the band pass filter, which reduces the gain outside the frequency range of interest, the stabilization tuner, which allows compensation for the circulator's limited isolation and the variable attenuator, which allows adjustment of the gain of the closed active loop; the prematching tuner matches the 50 Ω impedance of the circulator to the low impedance of the DUT, thus enabling the use of low or medium power, and therefore affordable, amplifiers in the set-up; the test set-up is capable of generating microwave reflection factors of up to 1.0 (VSWR=infinite) or higher, at the DUT reference plane, even if the inter-connections to the set-up are lossy (on-wafer operation).

### PRIORITY CLAIM

Not Applicable

### CROSS-REFERENCE TO RELATED ARTICLES

Product Note 42, “Active Modules for harmonic load pull measurements”, Focus Microwaves, April 1997

### STATEMENT REGARDING FEDERALLY SPONSORED RESEARCH OR DEVELOPEMENT

Not Applicable

### REFERENCE TO SEQUENCE LISTING, A TABLE, OR A COMPUTER PROGRAM LISTING COMPACT DISC APPENDIX

Not Applicable

### BACKGROUND OF THE INVENTION

This invention relates to a set-up for microwave load pull testing using an active tuner configuration improved by prematching and stabilization stages.

Modern design of high power microwave amplifiers and oscillators, used in various communication systems, requires accurate knowledge of the active device's (microwave transistor's) characteristics. In such circuits, it is inadequate for the transistors, which operate in their highly non-linear regime, close to power saturation, to be described using non-linear numeric models.

A popular method for testing and characterizing such microwave components (transistors) in the non-linear region of operation is “load pull”. Load pull is a measurement technique employing microwave tuners and other microwave test equipment. The microwave tuners are used in order to manipulate the microwave impedance conditions under which the Device Under Test (DUT, or transistor) is tested (FIGS. 1 and 2).

There are essentially two methods that allow generating and manipulating microwave impedances presented to the DUT:

A. Using electromechanical or passive electronic tuners, leading to “passive load pull” (FIG. 1); and;

B. Active tuners, leading to “active load pull” (FIG. 2).

Electro-mechanical slide screw tuners have a number of advantages like long-term stability, higher handling of microwave power, much easier operation and lower cost. Such tuners use adjustable mechanical obstacles (probes) in the transmission media of the tuners in order to reflect part of the power coming out of the DUT and create a “real” impedance presented to the DUT (device under test).

Active tuners are in fact microwave circuits, which include at least one microwave amplifier, that sample signals coming out of the DUT and return them to the DUT after amplifying it and modifying its amplitude and phase using the microwave circuit, creating a “virtual” impedance presented to the DUT.

In both cases, A. and B., it is possible to characterize the DUT properly, if other test conditions like harmonic impedances are controlled or are taken into account. The main difference between an “active” and a “passive” tuner system, as far as this patent is concerned, is the fact that an active system may generate load reflection factors, which are equal to or greater than 1.0 (a reflection factor of 1.0 corresponds to a real part of the microwave impedance of 0 Ω, reflection factor values>1.0 correspond to real parts of the microwave impedances of <0 Ω); passive tuners are limited in terms of reflection factor to values below 1, typically below 0.95 (corresponding to an impedance of 1.3 Ω). Considering unavoidable insertion loss between the DUT and the test port of a load pull tuner in a realistic test set-up, this means that a passive tuner can only allow testing of DUT's with internal impedances above roughly 2.0 Ω. Active tuner systems therefore allow one to test DUT's with lower internal impedance than passive systems, since the reflection factor can reach 1.0 and even compensate for insertion loss between the DUT and the tuner system. DUT's with impedances below 2.0 Ω can therefore not be tested using passive tuner systems, whereas active systems allow, in principle, this to be done.

FIGS. 1, 2 and 3 show prior art test set-ups that have been used for testing microwave power transistors. FIG. 1 shows a load pull test set-up using passive tuners; FIG. 2 shows one version of an active load pull test set-up, namely using an “active load” configuration; FIG. 3 shows a test set-up, which combines a passive tuner and an “active module”; an active module is a microwave circuit which is designed in order to increase the reflection factor of the passive tuner with which it is associated. The set-up of FIG. 3 works as follows: The signal delivered by the DUT at its output port (D2) at the DUT reference plane is injected into circulator port 1 (C1). This signal is forwarded via circulator port 2 (C2) into a Band-Pass Filter (16). The band-pass filter (16) is required in order to reduce the operating bandwidth of the closed electric loop comprising circulator 1 (7), the band-pass filter (16), circulator 2 (8), variable attenuator (18) and the power amplifier (15), and to reduce the risk of undesired spurious oscillations. The signal leaving the band-pass filter (16) is fed into circulator port 4 (C4) and into the input port of the passive load tuner (13) and the microwave load (14). The passive load tuner (13) creates a controlled reflection factor, which is smaller than 1.0 and sends part of the injected signal back into circulator port 5 (C5). This signal is then fed via circulator port 6 (C6) into the input port of the power amplifier (15) and then, via ports 3 (C3) and 1 (C1) of circulator 1 (7) back into the DUT output port (D2). The power ratio of the returned power wave (P_{ref1}) to the DUT output port (D2) and the power wave injected (Pᵢₙⱼ) by the DUT (12) into circulator port 1 (C1) is the complex microwave reflection factor seen by the DUT (12) at its output port (D2).

Γ=P_{ref1}/Pᵢₙⱼ. (1)

Because the power amplifier (15) amplifies the returned signal, P_{ref1}, it is possible to increase the level of P_{ref1} to a point, where it may become equal to, or even higher, than the injected power, Pᵢₙⱼ; in this case the reflection factor, _{Γ} (equation 1), presented at the DUT's output (D2) may become equal or even bigger than unity (1.0). In other words the circuit (Active Module) contained between the reference planes of DUT (12) and Tuner (13) helps increase the reflection factor of the passive tuner (13), and also compensate for any losses between the DUT output port (D2) and the circulator input port (C1). In this sense the Active Module “enhances” the reflection factor generated by any passive tuner. This is in particular important for set-ups on-wafer, where there are lossy cables and wafer probes included between the DUT and the load tuners, thus automatically reducing the effective reflection factor and the tuning range which the tuners can present to the DUT.

However there are two problems with this solution:

A. The limited isolation between port C4 and port C6 of the circulator 2 (8) causes an offset in tuning performance of the load tuner (13), as seen at the port C1 of circulator 1 (7) and bears a risk of unwanted spurious oscillation, if the total gain of the active loop exceeds 1.

B. There is a high mismatch factor between the low impedance of the DUT (12) at the output port (D2), which is typically 1 to 2 Ω or less, and the input impedance of circulator 1 (7), which is typically 50 Ω.

FIG. 4 shows a calibration data file of the circuit of a passive load pull tuner. The points shown in FIG. 4 correspond to the reflection factor seen at the input port of the tuner (13).

FIG. 5 shows a calibration data file of the set-up of FIG. 3 between the DUT reference plane and (but not including) the microwave load (14). The points shown in FIG. 5 correspond to the reflection seen at port C1 of circulator 1 (7), when the load tuner (13) is positioned at a number of tunable positions.

A. It can be seen that, whereas in FIG. 4 (tuner alone) the points are well distributed around the center of the Smith Chart and can reach values up to around 0.9 to 0.95. Seen from the circulator input port C4, the same points are off center, but they can reach values bigger than 1.0. The reason for this asymmetry is the limited isolation between ports C4 and C6 of circulator 2 (8). This, undesired, leak of signal not only creates asymmetry in the calibration pattern, but also increases the risk of spurious oscillations in the closed active loop comprising circulator 1 (7), the band-pass filter (16), circulator 2 (8), the variable attenuator (18) and the power amplifier (15) (FIG. 3). Typical values of the isolation between ports C4 and C6 of circulator 2 are 17-20 dB. The insertion loss of the band-pass filter is 2-4 dB; in this case it can easily be estimated that if the power amplifier has more than 20 dB of gain an undesired spurious oscillation is probable. In order to avoid this phenomenon, a technique is required to compensate for the limited isolation between ports C4 and C6.

B. The high mismatch between the output port impedance of the DUT and the circulator port C1, requires the use of very high power to be available from the power amplifier (15) (FIG. 3) in order to be able to effectively inject medium or even low power into the DUT output (D2), in order to be able to create an effective reflection factor.

FIG. 6 shows an electrical equivalent circuit of the set-up of FIG. 3, which allows calculating the required power of the power amplifier as a function of the DUT output impedance and output power for generating a reflection factor Γ=1.0. A simple calculation of the power P₁ available at the DUT input impedance, as a function of the available power P₀ of the power amplifier and the output impedance R of the DUT (assumed for simplicity not to have an imaginary part) delivers:

P₁/P₀=4*R₀*R₁/(R₀+R₁)² (2)

For an internal impedance of the circulator of R₀=50 Ω and an internal impedance of the DUT at its output port of R₁ and ignoring insertion losses between the output of the power amplifier (15) in FIG. 3 and the DUT output port (D2) we get as a minimum required power from the power amplifier values of:

R₁=1 Ω requires P₀ [dBm]=P₁ [dBm]+11.14 dB (3)

R₁=0.5 Ω requires P₀ [dBm]=P₁ [dBm]+14.07 dB (4)

Considering typical values of insertion loss due to adapters, cables etc. between the DUT output port (D2) and the output port of the power amplifier (15) (FIG. 3) to be approximately 2.0 dB then the power required from the power amplifier (15) will be approximately 13.0 dB (for R₁=1 Ω) and 17.0 dB (for R₁=0.5 Ω) higher than the power available at the DUT output port (D2), correspondingly. In case of a practical example: In order to test a power transistor (DUT) with an internal output impedance of 0.5 Ω, which delivers 2.0 Watt (≈33.0 dBm) output power, using either the set-up of FIG. 2 or the set-up of FIG. 3 (it is to be noticed that the set-up of FIG. 2 behaves, from power transfer point of view, identically as the set-up of FIG. 3), one needs a microwave power amplifier with available linear output power of at least 33.0 dBm+17 dBm=50.0 dBm (≈100 Watts). Such an amplifier in the GHz frequency range is very difficult to manufacture and very expensive, which, by consequence, makes the set-ups of FIGS. 2 and 3 impractical to configure and operate.

This invention comprises solutions to both above shortcomings of the set-up of FIG. 3, shown in FIG. 9, and, to the power transfer mismatch of the set-up of FIG. 2, shown in FIG. 10; this means that the set-up of FIG. 3 is improved by increasing the microwave stability and reducing spurious oscillations as well as reducing the output power required from the power amplifier (21) (FIG. 9) and that the set-up of FIG. 2 is improved by reducing the power required from the power amplifier (33), (FIG. 10).

### BRIEF SUMMARY OF THE INVENTION

We propose improvements to the set-ups in FIG. 3 and FIG. 2 as follows:

A. A manually adjustable or automatic microwave stabilization tuner (17) is inserted between the output port (C5) of circulator 2 (FIG. 3) and the input port of the load tuner (13); this said stabilization tuner reflects part of the incoming signal from circulator 2 back into port C5 and through to port C6 of circulator 2; said stabilization tuner can be adjusted such that the said reflected signal becomes of equal amplitude and opposite phase as the signal coming through the circulator 2, directly from port C4 to port C6 (or signal leakage); this way the total signal arriving at port C6 directly from port C4 and through reflection on port C5 is cancelled; This way the gain of the closed active module loop becomes close to 0 (or less than −20 dB), when the load tuner (13) is set to zero reflection. This proposed configuration is shown in FIG. 8.

B1. In the set-up of FIG. 9, which is an improvement of the set-up in FIG. 3, a manually adjustable or automatic tuner (2) is inserted between the output of the DUT (D2) and the input of the circulator 1 (C1). This tuner improves the mismatching conditions and power flow between the output of the DUT (12) and the input of circulator 1 (C1). A considerable amount of power requirement to meet the output power of the DUT, especially at very low internal impedances of the DUT, is therefore avoided.

B2. In the set-up of FIG. 10, which comprises the proposed improvement of the set-up in FIG. 2, a manually adjustable or automatic tuner (27) is inserted between the output of the DUT (D2) and the input of the directional coupler (31). This tuner (27) improves the mismatching conditions and power flow between the output of the DUT (26) and the input of the directional coupler (31). A considerable amount of power requirement to meet the output power of the DUT, especially at very low internal impedances of the DUT, is therefore avoided.

### BRIEF DESCRIPTION OF THE SEVERAL VIEWS OF THE DRAWINGS

The invention and its mode of operation will be more clearly understood from the following detailed description when read with the appended drawings in which:

FIG. 1 depicts Prior Art, a load pull set-up using passive tuners

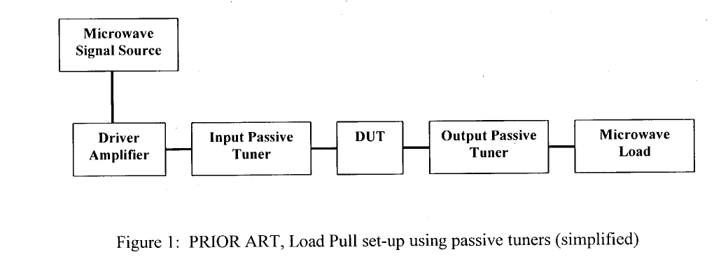

FIG. 2 depicts Prior Art, a load pull set-up using an active load (shown only the output side of the DUT)

FIG. 3 depicts Prior Art, a load pull set-up and the internal structure of an Active Load Module (11), used to increase the reflection factor of a passive tuner (13) seen by the DUT (12) at its output port (D2).

FIG. 4 depicts Prior Art, the distribution of calibration points of a typical passive microwave tuner (13) on the reflection factor surface (Smith Chart).

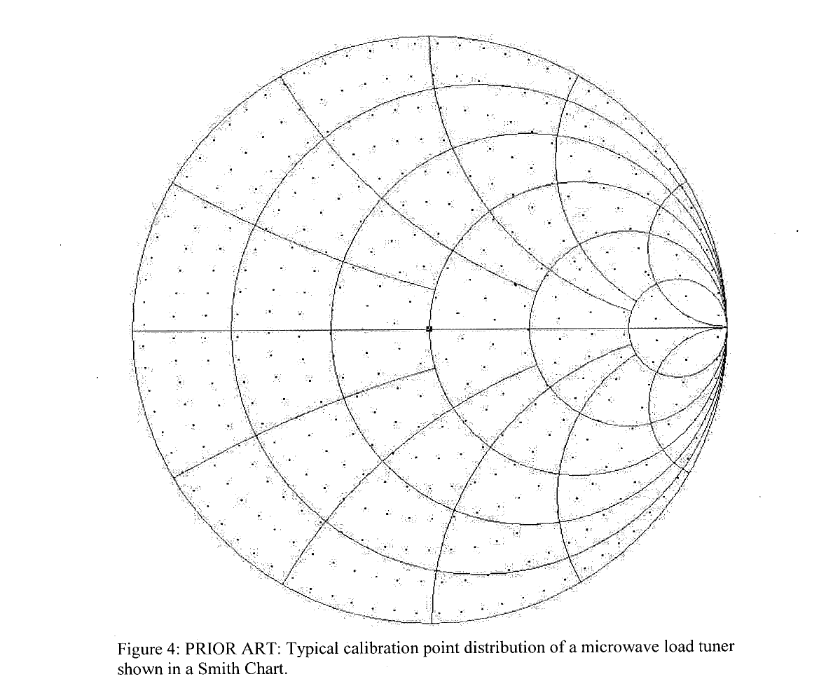

FIG. 5 depicts Prior Art, the distribution of calibration points of a typical cascade of an active load module (11) and a passive tuner (13) as shown in FIG. 3.

FIG. 6 depicts Prior Art, a simple electric equivalent circuit of an active load module, which describes the set-up of FIG. 3 between the DUT output port (D2), corresponding to resistor R1 and the output of the power amplifier (15) connected via the circulator (7).

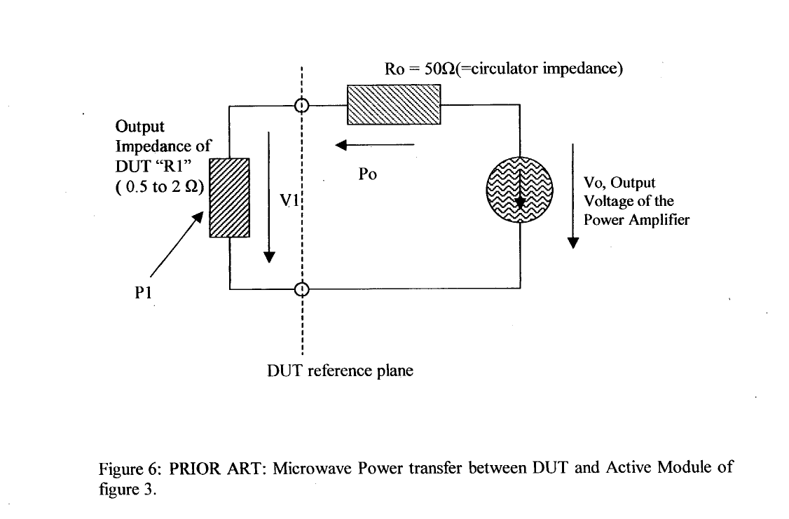

FIG. 7 depicts a load pull test set-up, comprising a prematching tuner stage (2) inserted between the DUT output port (D2) and the input port (C1) of circulator, which circulator is the input port of an active load module, as described in FIG. 3.

FIG. 8 depicts a load pull test set-up, comprising an active load module, as described in FIG. 3, and a stabilizing tuner stage (17), inserted between the output port of the active load module (C5) and the input port of the load tuner (13).

FIG. 9 depicts load pull test set-up, comprising a prematching tuner stage (2) inserted between the DUT output port (D2) and the input port (C1) of circulator, which circulator is the input port of an active load module, as described in FIG. 3, and a stabilizing tuner stage (17), inserted between the output port of the active load module (C5) and the input port of the load tuner (13).

FIG. 10 depicts load pull test set-up, comprising a prematching tuner stage (27) inserted between the DUT output port (D2) and the input port of a directional coupler (31), which is also the input port of the active load (32), as described in FIG. 2.

FIG. 11 depicts a diagram showing typical dependence of available loss of a passive tuner as a function of VSWR generated by this tuner.

FIG. 12 depicts the distribution of calibration points of a test set-up comprising an active load module (11) and a stabilizing section (17), shown in FIGS. 3 and 8.

FIG. 13 depicts a load pull impedance pattern distribution generated by special software routine, using the tuner calibration points of FIG. 12.

FIG. 14 depicts a set of load pull contours measured using a set-up similar to the set-up of FIG. 9, calibrated in order to test a DUT, which is a transistor with 1 Ω output impedance.

FIG. 15 depicts a three dimensional plot of the load pull contours of FIG. 14, showing how far high in reflection factor the measurement is smooth and reliable.

### DETAILED DESCRIPTION OF THE INVENTION

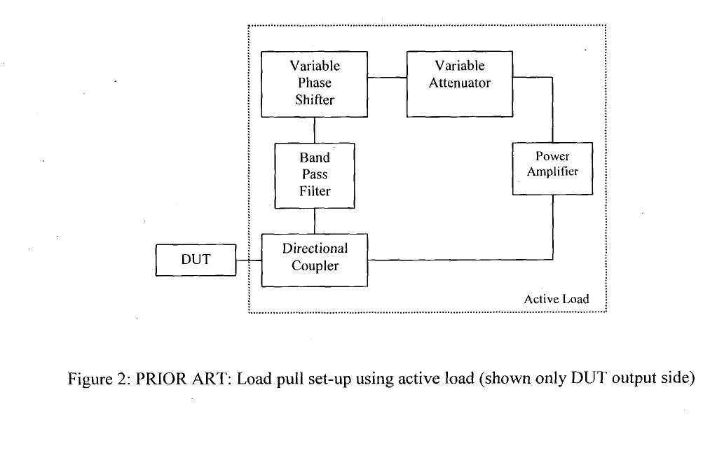

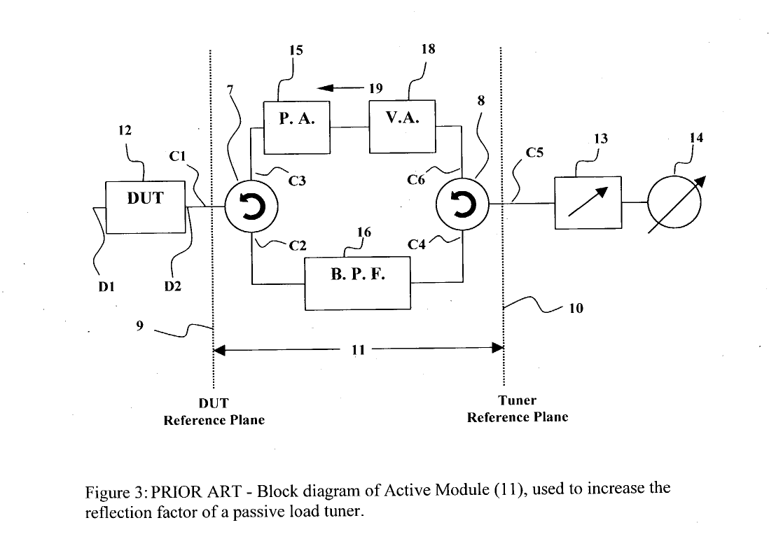

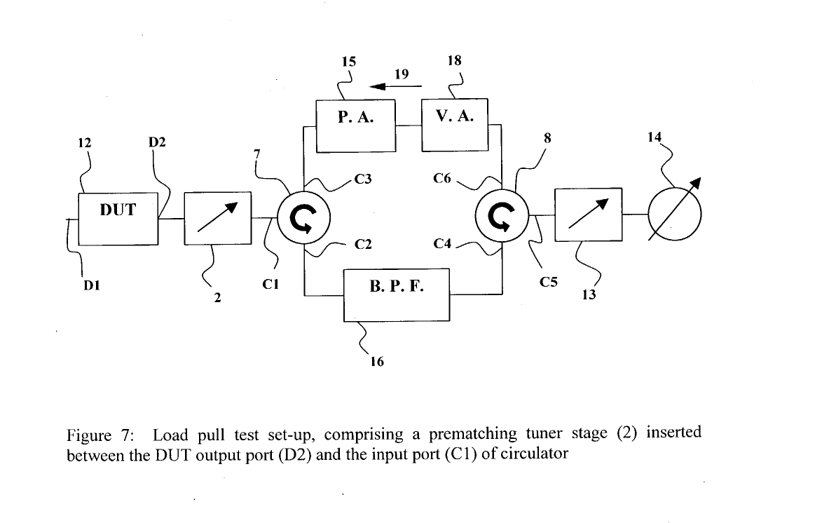

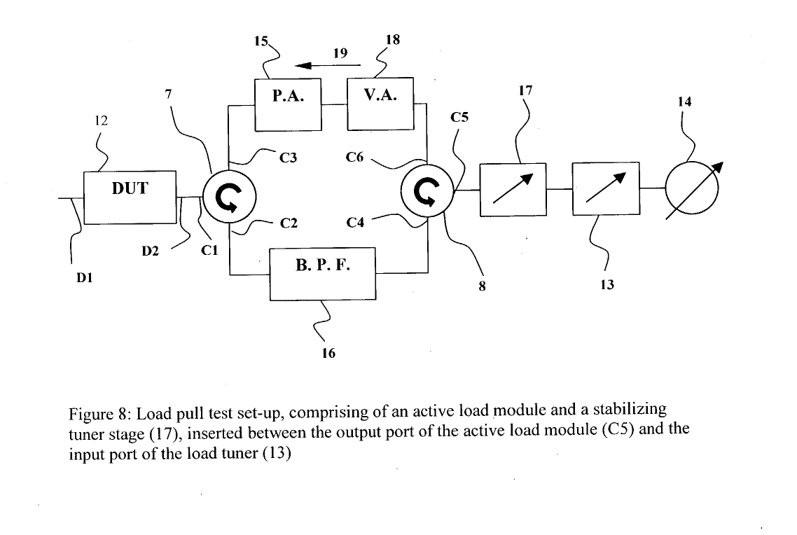

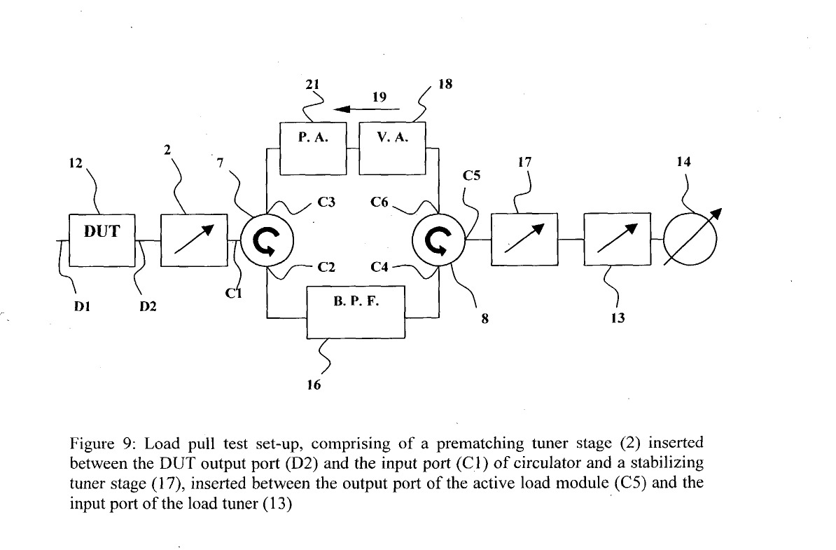

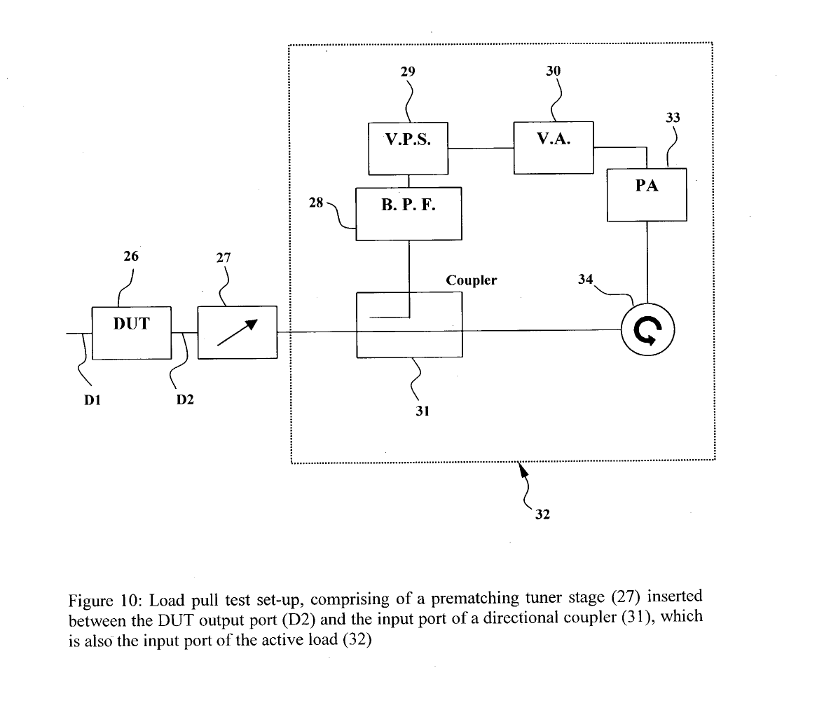

The proposed improvements to the set-up in FIG. 3 are shown in FIGS. 7 and 8. FIG. 7 shows the proposed method in order to improve the mismatching situation and power flow between the output of the DUT (12) and the input of circulator 1 (C1) by inserting a prematching tuner (2) between the DUT output (D2) and the input of the circulator (C1). FIG. 8 shows the proposed method in order to compensate for the finite isolation of circulator 2 (8), between ports C4 and C5, using an adjustable stabilization tuner (17). This stabilization tuner (17) is adjusted before the start of the measurement, so as to reflect part of the power coming from the circulator 2 (8) back into circulator 2 and create a signal vector at circulator port C6 opposite to the signal vector created by the signal leak from port C4 to port C6 of circulator 2 (8). FIG. 9 shows a set-up, which combines both improvement methods, i.e. a Prematching tuner stage (2) and a stabilization tuner stage (17). FIG. 10 shows the concept of the prematching tuner (27) inserted between the DUT output (D2) and the input of the active load in the set-up described in FIG. 2.

In the set-up of FIG. 7, the prematching tuner (2) between the DUT (12) and circulator (7) reduces the mismatch factor by, typically, a factor of 10, on both sides.

The mismatch factor M in this case is defined as:

M=R₀/R₁ (5)

Where R₀ and R₁ are the internal impedances of the two ports connected together. If R₀=R₁, we have a “matched” condition, when R₀≠ R₁, we have a “mis-matched” condition. In the case of the circulator (R₀=50 Ω) connected directly to a DUT (R₁=0.5 to 2 Ω), the mismatch factor varies from 100 to 25.

In other words, assuming the DUT (12) presents an internal impedance of 0.5 Ω at its output port (D2) and the circulator (7) has an input impedance of 50 Ω, then the corresponding VSWR would be 100:1. Using the prematching tuner (2) and adjusting it to a VSWR of 10:1 we obtain, on both ports of the tuner a VSWR of 10:1 (0.5 Ω) is transformed to 5 Ω by the tuner (2) and this corresponds to a VSWR of 10:1 towards the 50 Ω of the circulator (7)). In order for this technique to be really beneficial, the available loss of the tuner (2), under VSWR=10 tuning conditions, shall be much lower than the loss due to mismatch between the DUT (12) and circulator (7). Typical loss of tuners in the VSWR range of 10:1 is less than 0.5 dB, whereas the mismatch loss at the same VSWR of 10:1 calculated using equation (1) for R₁=5 Ω and R₀=50 Ω is 4.8 dB. The same gain exists on the interface between the DUT (12) and the tuner (2) assuming R₀=5 Ω and R₁=0.5 Ω.

In fact the way total reflection at the DUT output port (D2) is created in the set-up of FIG. 9 is that most of the power reflected back into the DUT (12) comes from the prematching tuner (2). The active module (AM) contributes only a small amount of reflected power; this also means that it is not required for the power amplifier to contribute high power. In fact, in order to create a reflection factor of close to 1.0, the power required by the power amplifier can be lower than the power available at the DUT output port (D2), in order to create a reflection factor of close to 1.0; tests have been done with a 1.0 Ω DUT in which case the power of the power amplifier is only slightly higher, equal or even lower that the power of the DUT (12), depending on the VSWR generated by the prematching tuner (2); Table 1 demonstrates these relationships.

TABLE 1
Power required from Power Amplifier to match a 1 Ω DUT for different
settings of the Prematching Tuner.

| | Output Power of DUT | Linear Power of Power |
|---|---|---|
| VSWR of | Matched @ 1 Ω | Amplifier (15) |
| Prematching Tuner (2) | (port D2) | at port C3 |
| 1:1 (50 Ω) or no tuner | 26.2 dBm (0.418 W) | 37 dBm (5 W) |
| 7:1 (7.15 Ω) | Same as above | 28 dBm (0.630 W) |
| 10:1 (5 Ω) | Same as above | 24.5 dBm (0.281 W) |

Table 1 shows that, in this particular case, the prematching tuner may reduce the requirement for high power amplifiers in the active module by as much as 12.5 dB (or a factor of around 18) when the prematching tuner is set to a 10:1 tuning ratio instead of 1:1 tuning ratio (37 dBm−24.5 dBm=12.5 dB); 1:1 tuning ratio meaning that the prematching tuner is not used at all as is the case in Prior Art.

Considering the importance of linearity (i.e. constant gain and constant transmission phase as a function of output power) of the power amplifier for the accuracy of the measurement in the pre-calibrated system, it is clear that the technique of employing a prematching tuner between the DUT and circulator 1 is decisive in making the setup operational.

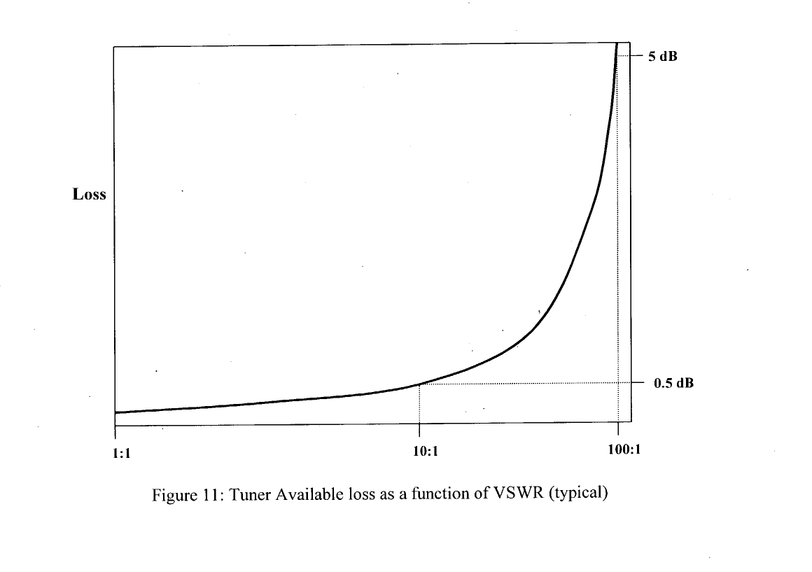

FIG. 11 shows the typical dependence of the available loss of the Prematching tuner (2) as a function of its tuning position expressed in voltage standing wave ratio (VSWR). At VSWR values of up to 10:1, the loss is low, typically 0.5 dB or less, somehow depending obviously also on tuner design and frequency. At VSWR values of 100:1, the loss is much higher, typically 5 dB or more. This shows that the Prematching tuner (2) should be operated around VSWR of 10:1 to enhance the power transfer between the active module (AM) and the DUT (12).

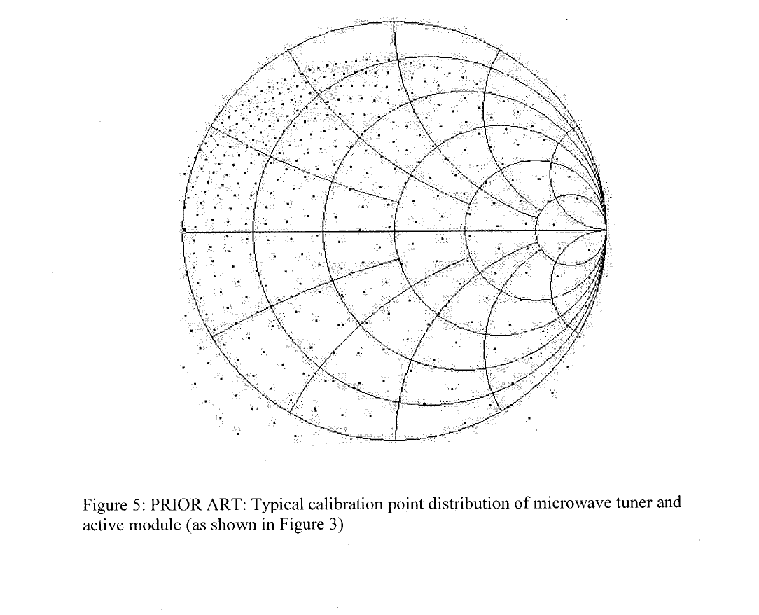

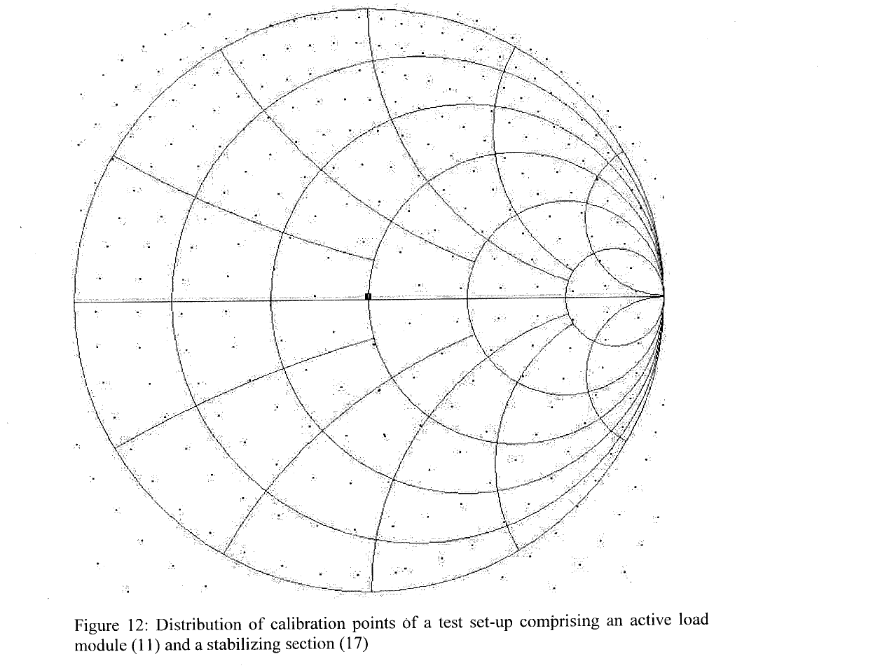

FIG. 12 shows the calibration points of the setup of FIG. 9 at the DUT reference plane (D2) when the Prematching tuner (2) is set to zero, thus representing a perfect transmission line. Compared with FIG. 5, it is evident that the stabilization tuner (17) allows compensating for the residual vector overlapping the calibration pattern due to the limited isolation between parts C4 and C6 of circulator (7).

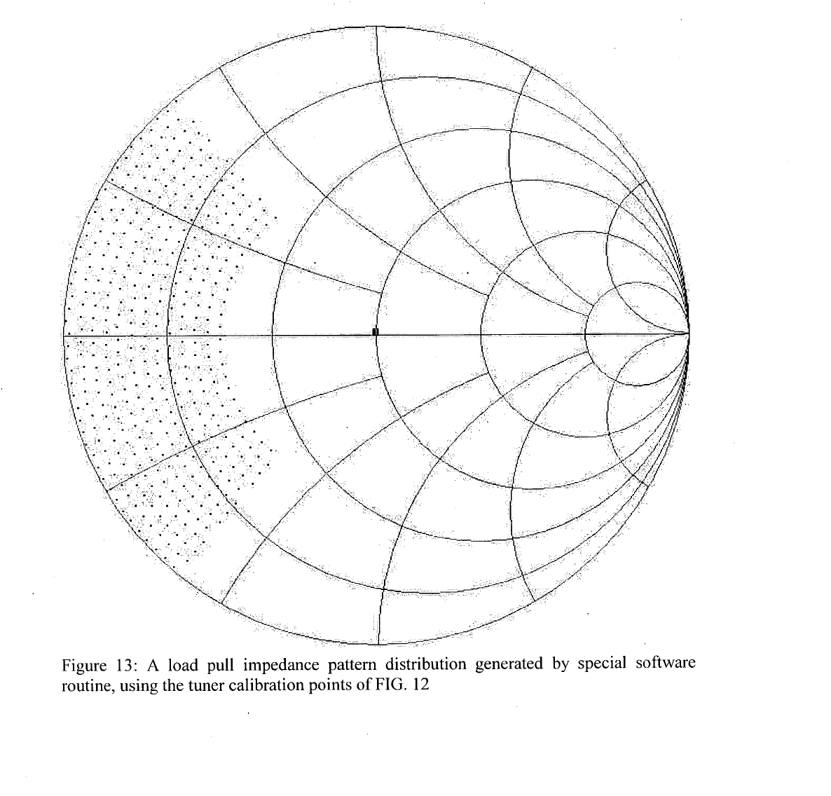

FIG. 13 shows a reflection factor pattern realized at DUT reference plane (D2) using tuning by the load tuner (13) to be used in load pull testing. The reflection factor pattern of the FIG. 13 shows that the test setup of the FIG. 9 allows effective testing of DUTs with output impedance well below 1.0 Ω. Tunable points shown in FIG. 13 correspond to values of 0.42 Ω, 1.0 Ω and higher, all at DUT reference plane and including insertion loss of 1.0 dB between the DUT output port (D2) and the input port of the test setup.

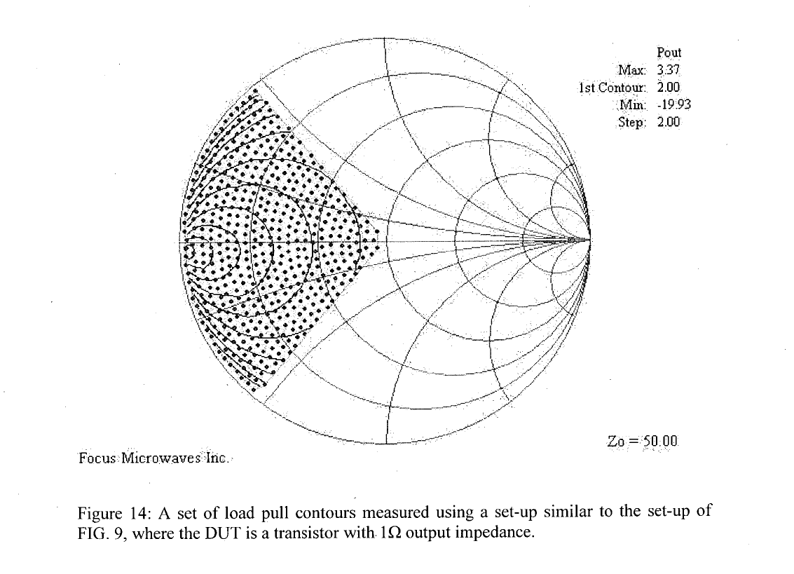

FIG. 14 shows a graph including load pull contours of a DUT, measured using a tuning pattern similar to the tuning pattern shown in FIG. 13 and realized using the same setup of FIG. 9, by tuning with the load tuner (13). It is obvious from FIG. 14 that the 1 Ω output impedance DUT can be effectively characterized using this setup. A criterion of successful characterization of a DUT using a load pull setup is when the contour lines, of gain or output power, are closed around the maximum point.

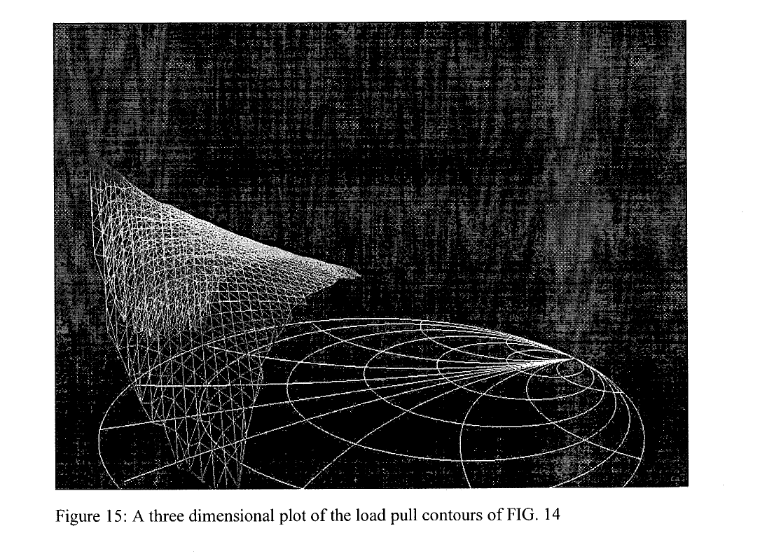

FIG. 15 shows a 3 dimensional plot of the same test result for which the contours on FIG. 14 have been drawn.

What I claim as my invention is:

1. A microwave load pull measurement set-up (stabilized active load module) comprising of a cascade of the following components: a circulator with its first port (input port) connected to the output port of a device under test (DUT); a band pass filter whose input port is connected to the second port (output port) of the circulator; a second circulator connected to the output port of the band pass filter; a stabilization tuner connected to the second port of the second circulator; a load tuner connected to the output port of the stabilization tuner, the output of the load tuner being connected to the microwave load of the set-up; the third port (return port) of the second circulator being connected to the input port of a variable attenuator; the output port of the variable attenuator being connected to the input port of a microwave power amplifier; the output port of the power amplifier being connected to the third port (return port) of the first circulator, closing thus the active module loop.

2. A microwave load pull measurement set-up (stabilized and prematched active load module) comprising a cascade of the following components: a prematching microwave tuner whose input port is connected to the output port of the device under test (DUT) and its output port is connected to the input port (port 1) of a circulator; a band pass filter whose input port is connected to the second port (output port) of the circulator; a second circulator connected to the output port of the band pass filter; a stabilization tuner connected to the second port of the second circulator; a load tuner connected to the output port of the stabilization tuner, the output port of the load tuner being connected to the microwave load of the set-up; the third port (return port) of the second circulator being connected to the input port of a variable attenuator; the output port of the variable attenuator being connected to the input port of a microwave power amplifier; the output port of the power amplifier being connected to the third port (return port) of the first circulator, closing thus the active module loop.

3. A microwave load pull measurement set-up (prematched active load module) comprising a cascade of the following components: a prematching microwave tuner whose input port is connected to the output port of the device under test (DUT) and its output port is connected to the input port (port 1) of a circulator; a band pass filter whose input port is connected to the second port (output port) of the circulator; a second circulator connected to the output port of the band pass filter; a load tuner connected to the output port of the stabilization tuner, the output port of the load tuner being connected to the microwave load of the set-up; the third port (return port) of the second circulator being connected to the input port of a variable attenuator; the output port of the variable attenuator being connected to the input port of a microwave power amplifier; the output port of the power amplifier being connected to the third port (return port) of the first circulator, closing thus the active module loop.

4. A microwave source pull measurement set-up (active source module) comprising a cascade of the following components: a microwave source tuner whose input is connected to the signal source of the set-up; a first circulator whose input port is connected to the output port of the source tuner; a band pass filter whose input port is connected to the second port of the first circulator and output port is connected to the input port (port 1) of a second circulator; the second port of the second circulator being connected to the input port of the device under test (DUT); the third port (return port) of the second circulator being connected to the input port of a variable microwave attenuator, whose output port is connected to the input port of a power amplifier; the output port of the power amplifier being connected to the third port (return port) of the first circulator, closing thus the active module loop.

5. A microwave source pull measurement set-up (stabilized active source module) comprising a cascade of the following components: a microwave source tuner whose input is connected to the signal source of the set-up; a stabilization tuner whose input port is connected to the output port of the source tuner and whose output port is connected to the input port (input port) of a first circulator whose input port is connected to the output port of the source tuner; a band pass filter whose input port is connected to the second port of the first circulator and output port is connected to the input port (port 1) of a second circulator; the second port of the second circulator being connected to the input port of the device under test (DUT); the third port (return port) of the second circulator being connected to the input port of a variable microwave attenuator, whose output port is connected to the input port of a power amplifier; the output port of the power amplifier being connected to the third port (return port) of the first circulator, closing thus the active module loop.

6. A microwave source pull measurement set-up (stabilized and prematched active source module) comprising a cascade of the following components: a microwave source tuner whose input port is connected to the signal source of the set-up; a stabilization tuner whose input port is connected to the output port of the source tuner and whose output port is connected to the first port (input port) of a first circulator; a band pass filter whose input port is connected to the second port (output port) of the first circulator and output port is connected to the input port of a second circulator; the second port (output port) of the second circulator being connected to the input port of a prematching tuner, whose output port is connected to the input port of the device under test (DUT); the third port (return port) of the second circulator being connected to the input port of a variable microwave attenuator, whose output port is connected to the input port of a power amplifier; the output port of the power amplifier being connected to the third port (return port) of the first circulator, closing thus the active module loop.

7. A microwave source pull measurement set-up (prematched active source module) comprising a cascade of the following components: a microwave source tuner whose input is connected to the signal source of the set-up and whose output port is connected to the first port (input port) of a first circulator; a band pass filter whose input port is connected to the second port (output port) of the first circulator and output port is connected to the input port of a second circulator; the second port of the second circulator being connected to the input port of a prematching tuner whose output port is connected to the input port of the device under test (DUT); the third port (return port) of the second circulator being connected to the input port of a variable microwave attenuator, whose output port is connected to the input port of a power amplifier; the output port of the power amplifier being connected to the third port (return port) of the first circulator, closing thus the active module loop.

8. A microwave load pull measurement set-up (prematched active load) comprising a cascade of the following components: a prematching microwave tuner whose input port is connected to the output port of the device under test (DUT) and its output port is connected to the input port 1 of a directional coupler; a band pass filter (B.P.F.) whose input port is connected to the coupled port 3 of the directional coupler and whose output port is connected to the input port of a variable phase shifter (V.P.S.); the output port of the phase shifter being connected to the input port of a variable attenuator (V.A.) whose output port is connected to the input port of a power amplifier (P.A.); the output port of the power amplifier being connected directly or through a circulator to the through port 2 (return port) of the directional coupler.
